(19) United States
(12) Patent Application Publication
(10) Pub. No.: US 2008/0272354 A1
(43) Pub. Date: Nov. 6, 2008

(54) PHASE CHANGE DIODE MEMORY

(76) Inventors: Thomas Nirschl, Essex Junction, VT (US); Thomas Happ, Tarrytown, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/744,460

(22) Filed: May 4, 2007

(51) Int. Cl. H01L 29/02; H01L 21/00

(52) U.S. Cl. 257/2; 438/104; 257/E29.002

(57) ABSTRACT

An integrated circuit having a memory includes a semiconductor line and a phase change element contacting the semiconductor line. The phase change element provides a storage location. A diode junction is formed at the interface between the semiconductor line and the phase change element.

### BACKGROUND

One type of memory is resistive memory. Resistive memory utilizes the resistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory. Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store bits of data. In the following description, the amorphous state generally refers to the state having the higher resistivity and the crystalline state generally refers to the state having the lower resistivity.

Phase changes in the phase change materials may be induced reversibly. In this way, the memory may change from the amorphous state to the crystalline state and from the crystalline state to the amorphous state in response to temperature changes. The temperature changes to the phase change material may be achieved by driving current through the phase change material itself or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The level of current and/or voltage generally corresponds to the temperature induced within the phase change material in each memory cell.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. To program a phase change memory cell to an intermediate resistance value, the amount of crystalline material coexisting with amorphous material and hence the cell resistance is controlled via a suitable write strategy.

Higher density phase change memories can also be achieved by reducing the physical size of each memory cell. Increasing the density of a phase change memory increases the amount of data that can be stored within the memory while at the same time typically reducing the cost of the memory.

For these and other reasons, there is a need for the present invention.

### SUMMARY

One embodiment provides an integrated circuit having a memory. The integrated circuit includes a semiconductor line and a phase change element contacting the semiconductor line. The phase change element provides a storage location. A diode junction is formed at the interface between the semiconductor line and the phase change element.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of a memory device.

FIG. 2 illustrates a cross-sectional view of one embodiment of an array of phase change memory cells.

FIG. 3 illustrates a cross-sectional view of another embodiment of an array of phase change memory cells.

FIG. 4 illustrates a cross-sectional view of another embodiment of an array of phase change memory cells.

FIG. 5 illustrates a cross-sectional view of one embodiment of word lines formed in a substrate.

FIG. 6 illustrates a cross-sectional view of another embodiment of word lines formed in a substrate.

FIG. 7 illustrates a cross-sectional view of one embodiment of the word lines, a phase change material layer, and an electrode material layer.

FIG. 8 illustrates a cross-sectional view of one embodiment of the word lines, the phase change material layer, and the electrode material layer after etching the electrode material layer.

FIG. 9 illustrates a cross-sectional view of one embodiment of the word lines, diode junctions, phase change elements, and heater contacts after etching the electrode material layer and the phase change material layer.

FIG. 10 illustrates a cross-sectional view of one embodiment of the word lines, the phase change material layer, the heater contacts, and a spacer material layer.

FIG. 11 illustrates a cross-sectional view of one embodiment of the word lines, the phase change material layer, the heater contacts, and spacers after etching the spacer material layer.

FIG. 12 illustrates a cross-sectional view of one embodiment of the word lines, diode junctions, phase change elements, the heater contacts, and the spacers after etching the phase change material layer.

FIG. 13 illustrates a cross-sectional view of one embodiment of the word lines, the diode junctions, the phase change elements, the heater contacts, and dielectric material.

FIG. 14 illustrates a cross-sectional view of one embodiment of the word lines, the phase change material layer, and a dielectric or sacrificial material layer.

FIG. 15 illustrates a cross-sectional view of one embodiment of the word lines, the phase change material layer, and the dielectric or sacrificial material layer after etching the dielectric or sacrificial material layer.

FIG. 16 illustrates a cross-sectional view of one embodiment of the word lines, the phase change material layer, the dielectric or sacrificial material layer, and a spacer material layer.

FIG. 17 illustrates a cross-sectional view of one embodiment of the word lines, the phase change material layer, the dielectric or sacrificial material layer, and spacers after etching the spacer material layer.

FIG. 18 illustrates a cross-sectional view of one embodiment of the word lines, the phase change material layer, the dielectric or sacrificial material layer, the spacers, and heater contacts.

FIG. 19 illustrates a cross-sectional view of one embodiment of the word lines, diode junctions, phase change elements, the heater contacts, and the spacers after removing the dielectric or sacrificial material layer and etching the phase change material layer.

FIG. 20 illustrates a cross-sectional view of one embodiment of the word lines, the diode junctions, the phase change elements, the heater contacts, the spacers, and a dielectric material.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

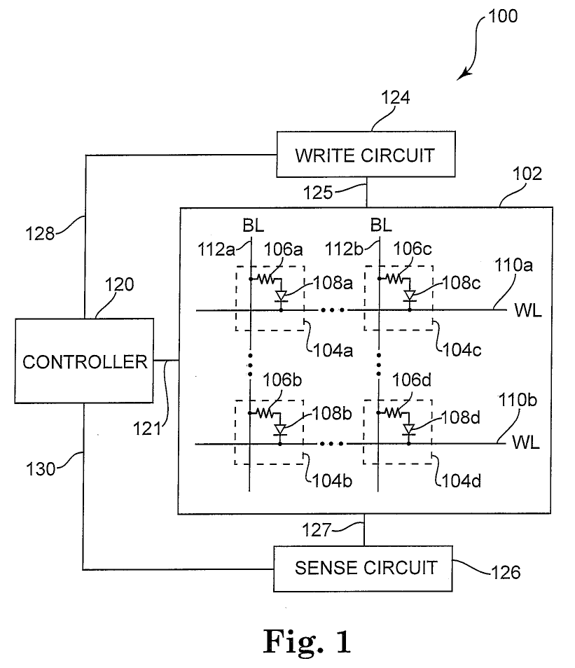

FIG. 1 is a diagram illustrating one embodiment of a memory device 100. Memory device 100 includes a write circuit 124, a controller 120, a memory array 102, and a sense circuit 126. Memory array 102 includes a plurality of resistive memory cells 104a-104d (collectively referred to as resistive memory cells 104), a plurality of bit lines (BLs) 112a-112b (collectively referred to as bit lines 112), and a plurality of word lines (WLs) 110a-110b (collectively referred to as word lines 110). In one embodiment, resistive memory cells 104 are phase change memory cells. In other embodiments, resistive memory cells 104 are another suitable type of resistive memory cells or resistivity changing memory cells.

Each memory cell 104 includes a phase change element 106 and a diode 108 formed using phase change element 106 for either the p-type or n-type portion of the pn junction forming diode 108. In one embodiment, a heater contact is used to separate the phase change region in a phase change element 106 from the diode junction to improve the reliability of the memory. By using diodes 108 to select bits within memory array 102, a 4 F² memory cell size is achieved, where “F” is the minimum feature size.

As used herein, the term “electrically coupled” is not meant to mean that the elements must be directly coupled together and intervening elements may be provided between the “electrically coupled” elements.

Memory array 102 is electrically coupled to write circuit 124 through signal path 125, to controller 120 through signal path 121, and to sense circuit 126 through signal path 127. Controller 120 is electrically coupled to write circuit 124 through signal path 128 and to sense circuit 126 through signal path 130. Each phase change memory cell 104 is electrically coupled to a word line 110 and a bit line 112. Phase change memory cell 104a is electrically coupled to bit line 112a and word line 110a, and phase change memory cell 104b is electrically coupled to bit line 112a and word line 110b. Phase change memory cell 104c is electrically coupled to bit line 112b and word line 110a, and phase change memory cell 104d is electrically coupled to bit line 112b and word line 110b.

Each phase change memory cell 104 includes a phase change element 106 and a diode 108. Diode 108 is formed using phase change element 106 for either the p-type or n-type portion of the pn junction of diode 108. Phase change memory cell 104a includes phase change element 106a and diode 108a. One side of phase change element 106a is electrically coupled to bit line 112a, and the other side of phase change element 106a provides one side of diode 108a. The other side of diode 108a is electrically coupled to word line 110a.

Phase change memory cell 104b includes phase change element 106b and diode 108b. One side of phase change element 106b is electrically coupled to bit line 112a, and the other side of phase change element 106b provides one side of diode 108b. The other side of diode 108b is electrically coupled to word line 110b.

Phase change memory cell 104c includes phase change element 106c and diode 108c. One side of phase change element 106c is electrically coupled to bit line 112b and the other side of phase change element 106c provides one side of diode 108c. The other side of diode 108c is electrically coupled to word line 110a.

Phase change memory cell 104d includes phase change element 106d and diode 108d. One side of phase change element 106d is electrically coupled to bit line 112b and the other side of phase change element 106d provides one side of diode 108d. The other side of diode 108d is electrically coupled to word line 110b.

In another embodiment, each phase change element 106 is electrically coupled to a word line 110 and each diode 108 is electrically coupled to a bit line 112. For example, for phase change memory cell 104a, one side of phase change element 106a is electrically coupled word line 110a. The other side of phase change element 106a provides one side of diode 108a. The other side of diode 108a is electrically coupled to bit line 112a.

In one embodiment, each resistive memory element 106 is a phase change element that comprises a phase change material that may be made up of a variety of materials in accordance with the present invention. Generally, chalcogenide alloys that contain one or more elements from Group VI of the periodic table are useful as such materials. In one embodiment, the phase change material is made up of a chalcogenide compound material, such as GeSbTe, SbTe, GeTe, or AgInSbTe. In another embodiment, the phase change material is chalcogen free, such as GeSb, GaSb, InSb, or GeGaInSb. In other embodiments, the phase change material is made up of any suitable material including one or more of the elements Ge, Sb, Te, Ga, As, In, Se, and S.

Each phase change element may be changed from an amorphous state to a crystalline state or from a crystalline state to an amorphous state under the influence of temperature change. The amount of crystalline material coexisting with amorphous material in the phase change material of one of the phase change elements thereby defines two or more states for storing data within memory device 100. In the amorphous state, a phase change material exhibits significantly higher resistivity than in the crystalline state. Therefore, the two or more states of the phase change elements differ in their electrical resistivity. In one embodiment, the two or more states are two states and a binary system is used, wherein the two states are assigned bit values of “0” and “1”. In another embodiment, the two or more states are three states and a ternary system is used, wherein the three states are assigned bit values of “0”, “1”, and “2”. In another embodiment, the two or more states are four states that are assigned multi-bit values, such as “00”, “01”, “10”, and “11”. In other embodiments, the two or more states can be any suitable number of states in the phase change material of a phase change element.

Controller 120 includes a microprocessor, microcontroller, or other suitable logic circuitry for controlling the operation of memory device 100. Controller 120 controls read and write operations of memory device 100 including the application of control and data signals to memory array 102 through write circuit 124 and sense circuit 126. In one embodiment, write circuit 124 provides voltage pulses through signal path 125 and bit lines 112 to memory cells 104 to program the memory cells. In other embodiments, write circuit 124 provides current pulses through signal path 125 and bit lines 112 to memory cells 104 to program the memory cells.

Sense circuit 126 reads each of the two or more states of memory cells 104 through bit lines 112 and signal path 127. In one embodiment, to read the resistance of one of the memory cells 104, sense circuit 126 provides current that flows through one of the memory cells 104. Sense circuit 126 then reads the voltage across that one of the memory cells 104. In another embodiment, sense circuit 126 provides voltage across one of the memory cells 104 and reads the current that flows through that one of the memory cells 104. In another embodiment, write circuit 124 provides voltage across one of the memory cells 104 and sense circuit 126 reads the current that flows through that one of the memory cells 104. In another embodiment, write circuit 124 provides current that flows through one of the memory cells 104 and sense circuit 126 reads the voltage across that one of the memory cells 104.

In one embodiment, during a “set” operation of a phase change memory cell 104a, a set current or voltage pulse is selectively enabled by write circuit 124 and sent through bit line 112a to phase change element 106a thereby heating phase change element 106a above its crystallization temperature (but usually below its melting temperature). In this way, phase change element 106a reaches its crystalline state or a partially crystalline and partially amorphous state during this set operation. During a “reset” operation of phase change memory cell 104a, a reset current or voltage pulse is selectively enabled by write circuit 124 and sent through bit line 112a to phase change element 106a. The reset current or voltage quickly heats phase change element 106a above its melting temperature. After the current or voltage pulse is turned off, phase change element 106a quickly quench cools into the amorphous state or a partially amorphous and partially crystalline state.

Phase change memory cells 104b-104d and other phase change memory cells 104 in memory array 102 are set and reset similarly to phase change memory cell 104a using a similar current or voltage pulse. In other embodiments, for other types of resistive memory cells, write circuit 124 provides suitable programming pulses to program the resistive memory cells 104 to the desired state.

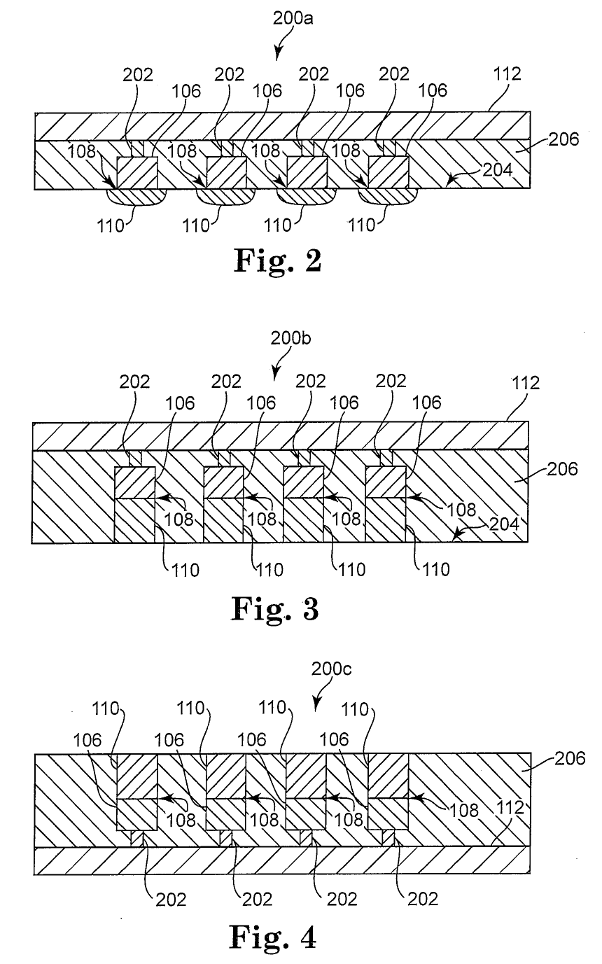

FIG. 2 illustrates a cross-sectional view of one embodiment of an array of phase change memory cells 200a. Array of phase change memory cells 200a includes word lines 110, diode junctions 108, phase change elements 106, heater contacts 202, bit lines 112, dielectric material 206, and substrate 204. Word lines 110 and phase change elements 106 form a pn or diode junction at the interface between each word line 110 and phase change element 106. In one embodiment, word lines 110 include an n-type semiconductor and phase change elements 106 include a p-type phase change material. In another embodiment, word lines 110 include a p-type semiconductor and phase change elements 106 include an n-type phase change material. In another embodiment, a Schottky junction is formed between the word lines 110 and phase change elements 106.

Word lines 110 are formed by implantation of dopants into substrate 204. Phase change elements 106 contact portions of word lines 110 to form diode junctions 108 at the interface between each word line 110 and phase change element 106. Each phase change element 106 is electrically coupled to a heater contact 202. In one embodiment, heater contacts 202 have a sublithographic cross-sectional width. A storage location for storing one or more bits of data is formed in each phase change element 106 at the interface of each phase change element 106 and heater contact 202. Each heater contact 202 is electrically coupled to a bit line 112. Dielectric material 206 laterally surrounds phase change elements 106 and heater contacts 202 to provide electrical isolation.

FIG. 3 illustrates a cross-sectional view of another embodiment of a phase change memory array 200b. Phase change memory array 200b is similar to phase change memory array 200a previously described and illustrated with reference to FIG. 2, except that in phase change memory array 200b, word lines 110 are fabricated on top of substrate 204 by deposition and etching rather than by implanting dopants into substrate 204. A diode junction 108 is formed at the interface between each word line 110 and phase change element 106. A storage location for storing one or more bits of data is formed in each phase change element 106 at the interface of each phase change element 106 and heater contact 202.

FIG. 4 illustrates a cross-sectional view of another embodiment of a phase change memory array 200c. Phase change memory array 200c is similar to phase change memory array 200b previously described and illustrated with reference to FIG. 3, except that in phase change memory array 200c, the entire structure is turned over. Bits lines 112 are formed above substrate 204. Heater contacts 202 are formed above and contacting bit lines 112. Phase change elements 106 and formed above and contacting heater contacts 202. Word lines 110 are formed above and contacting phase change elements 106. In one embodiment, word lines 110 and bit lines 112 are interchanged. In one embodiment, a pn junction 108 is formed at the interface between each word line 110 and phase change element 106. In another embodiment, a Schottky junction 108 is formed at the interface between each word line 110 and phase change element 106. A storage location for storing one or more bits of data is formed in each phase change element 106 at the interface of each phase change element 106 and heater contact 202.

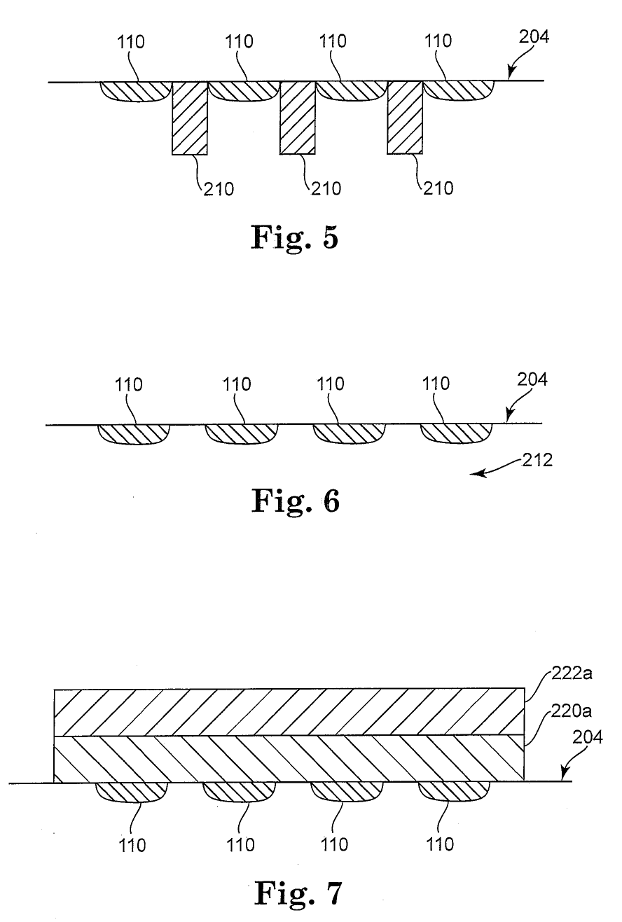

The following FIGS. 5-20 illustrate embodiments of a process for fabricating a phase change memory array, such as phase change memory array 200a previously described and illustrated with reference to FIG. 2.

FIG. 5 illustrates a cross-sectional view of one embodiment of word lines 110 formed in substrate 204. In one embodiment, shallow trench isolation (STI) 210 is formed in substrate 204. Using shallow trench isolation 210 as an implant mask, n-type or p-type dopants are implanted into substrate 204 to form word lines 110.

FIG. 6 illustrates a cross-sectional view of another embodiment of word lines 110 formed in substrate 204. In this embodiment, n-type or p-type dopants are implanted into a p-type or n-type well 212, respectively, to form word lines 110. In one embodiment, word lines 110 are formed by n-type implants into a p-type well 212. In another embodiment, word lines 110 are formed by p-type implants into an n-type well 212.

FIG. 7 illustrates a cross-sectional view of one embodiment of word lines 110, a phase change material layer 220a, and an electrode material layer 222a. A phase change material, such as a chalcogenide compound material or other suitable phase change material is deposited over word lines 110 and substrate 204 to provide phase change material layer 220a. Phase change material layer 220a is deposited using chemical vapor deposition (CVD), atomic layer deposition (ALD), metal organic chemical vapor deposition (MOCVD), plasma vapor deposition (PVD), jet vapor deposition (JVD), or other suitable deposition technique.

Electrode material, such as TiN, TaN, W, Al, Ti, Ta, TiSiN, TaSiN, TiAlN, TaAlN, Cu, or other suitable electrode material is deposited over phase change material layer 220a to provide electrode material layer 222a. Electrode material layer 222a is deposited using CVD, ALD, MOCVD, PVD, JVD, or other suitable deposition technique.

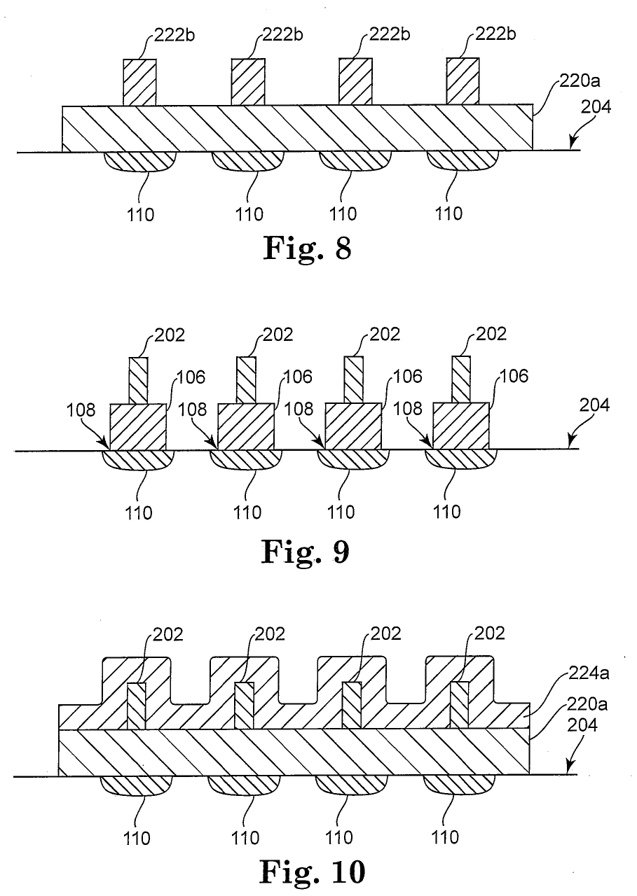

FIG. 8 illustrates a cross-sectional view of one embodiment of word lines 110, phase change material layer 220a, and electrode material layer 222b after etching electrode material layer 222a. Electrode material layer 222a is patterned using photolithography or other suitable process and etched to expose portions of phase change material layer 220a and to provide electrode material layer 222b. Electrode material layer portions 222b are substantially centered over word lines 110. In one embodiment, a resist trim process, back etch, or other suitable thinning technique is used to create electrode material layer portions 222b having sublithographic cross-sectional widths.

FIG. 9 illustrates a cross-sectional view of one embodiment of word lines 110, diode junctions 108, phase change elements 106, and heater contacts 202 after thinning electrode material layer portions 222b as discussed with reference to FIG. 8 and etching phase change material layer 220a. In one embodiment, heater contacts 202 have sublithographic cross-sectional widths and are substantially centered over phase change elements 106. Phase change material layer 220a is etched to expose portions of substrate 204 and to provide phase change elements 106. A diode junction is formed at the interface between each word line 110 and phase change element 106.

In another embodiment, phase change elements 106 are fabricated by first depositing a dielectric material, such as SiO₂, SiOₓ, SiN, fluorinated silica glass (FSG), boro-phosphorus silicate glass (BPSG), boro-silicate glass (BSG), or other suitable dielectric material over word lines 110 and substrate 204 illustrated in FIG. 6 to provide a dielectric material layer. The dielectric material layer is deposited using CVD, ALD, MOCVD, PVD, JVD, or other suitable deposition technique. The dielectric material layer is then etched to provide openings exposing portions of word lines 110. A phase change material, such as a chalcogenide compound material or other suitable phase change material is deposited over the etched dielectric material layer and exposed portions of word lines 110 to provide a phase change material layer. The phase change material layer is deposited using CVD, ALD, MOCVD, PVD, JVD, or other suitable deposition technique. The phase change material layer is then planarized using chemical mechanical planarization (CMP) or other suitable planarization technique to expose the etched dielectric material layer and to provide phase change elements 106.

The following FIGS. 10-12 illustrate an alternative embodiment for fabricating phase change elements 106.

FIG. 10 illustrates a cross-sectional view of one embodiment of word lines 110, phase change material layer 220a, heater contacts 202, and a spacer material layer 224a. A spacer material, such as SiN or other suitable dielectric material is conformally deposited over exposed portions of heater contacts 202 and phase change material layer 220a to provide spacer material layer 224a. Spacer material layer 224a is deposited using CVD, ALD, MOCVD, PVD, JVD, or other suitable deposition technique.

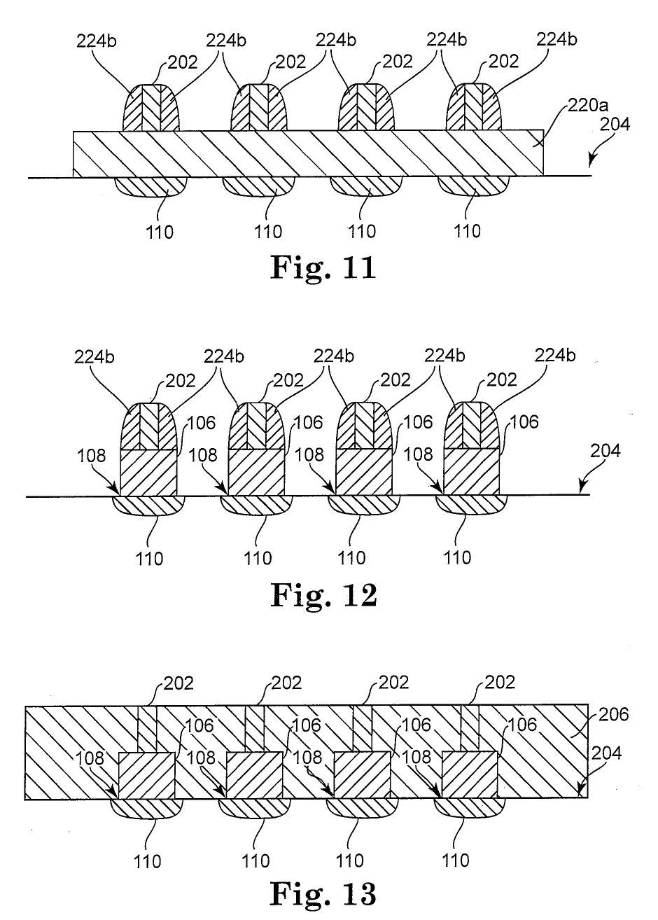

FIG. 11 illustrates a cross-sectional view of one embodiment of word lines 110, phase change material layer 220a, heater contacts 202, and spacers 224b after etching spacer material layer 224a. Spacer material layer 224a is spacer etched to expose the top of heater contacts 202 and portions of phase change material layer 220a.

FIG. 12 illustrates a cross-sectional view of one embodiment of word lines 110, diode junctions 108, phase change elements 106, heater contacts 202, and spacers 224b after etching phase change material layer 220a. The exposed portions of phase change material layer 220a are etched to expose portions of substrate 204 and to provide phase change elements 106. A diode junction is formed at the interface of each word line 110 and phase change element 106. A storage location for storing one or more bits of data is formed in each phase change element 106 at the interface of each phase change element 106 and heater contact 202.

FIG. 13 illustrates a cross-sectional view of one embodiment of word lines 110, diode junctions 108, phase change elements 106, heater contacts 202, and dielectric material 206. Dielectric material, such as SiO₂, SiOₓ, SiN, FSG, BPSG, BSG, or other suitable dielectric material is deposited over exposed portions of heater contacts 202, phase change elements 106, and substrate 204 (for FIG. 9) or over exposed portions of heater contacts 202, spacers 224b, phase change elements 106, and substrate 204 (for FIG. 12). The dielectric material layer is then planarized using CMP or other suitable planarization technique to expose heater contacts 202. Bit lines 112 are then formed over heater contacts 202 to provide array of phase change memory cells 200a as previously described and illustrated with reference to FIG. 2.

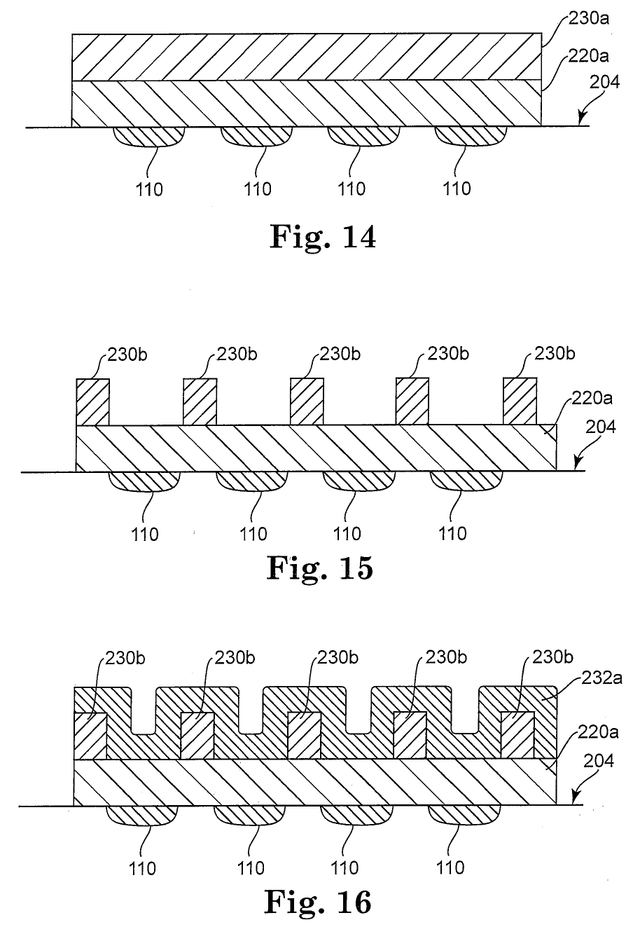

The following FIGS. 14-20 illustrate another embodiment for fabricating a phase change memory array similar to phase change memory array 200a previously described and illustrated with reference to FIG. 2. To begin, the process previously described and illustrated with reference to FIGS. 5 or 6 is performed.

FIG. 14 illustrates a cross-sectional view of one embodiment of word lines 110, a phase change material layer 220a, and a dielectric or sacrificial material layer 230a. A phase change material, such as a chalcogenide compound material or other suitable phase change material is deposited over word lines 110 and substrate 204 to provide phase change material layer 220a. Phase change material layer 220a is deposited using CVD, ALD, MOCVD, PVD, JVD, or other suitable deposition technique.

A dielectric material, such as SiO₂, SiOₓ, SiN, FSG, BPSG, BSG, or other suitable dielectric material, or a sacrificial material, such as C or other suitable sacrificial material is deposited over phase change material layer 220a to provide dielectric or sacrificial material layer 230a. Dielectric or sacrificial material layer 230a is deposited using CVD, ALD, MOCVD, PVD, JVD, or other suitable deposition technique.

FIG. 15 illustrates a cross-sectional view of one embodiment of word lines 110, phase change material layer 220a, and dielectric or sacrificial material layer 230b after etching dielectric or sacrificial material layer 230a. Dielectric or sacrificial material layer 230a is etched to expose portions of phase change material layer 220a and to provide dielectric or sacrificial material layer portions 230b. Each dielectric or sacrificial material layer portion 230b is substantially centered between word lines 110.

FIG. 16 illustrates a cross-sectional view of one embodiment of word lines 110, phase change material layer 220a, dielectric or sacrificial material layer 230b, and a spacer material layer 232a. A spacer material, such as SiN or other suitable dielectric material is conformally deposited over exposed portions of dielectric or sacrificial material layer 230b and phase change material layer 220a to provide spacer material layer 232a. Spacer material layer 232a is deposited using CVD, ALD, MOCVD, PVD, JVD, or other suitable deposition technique.

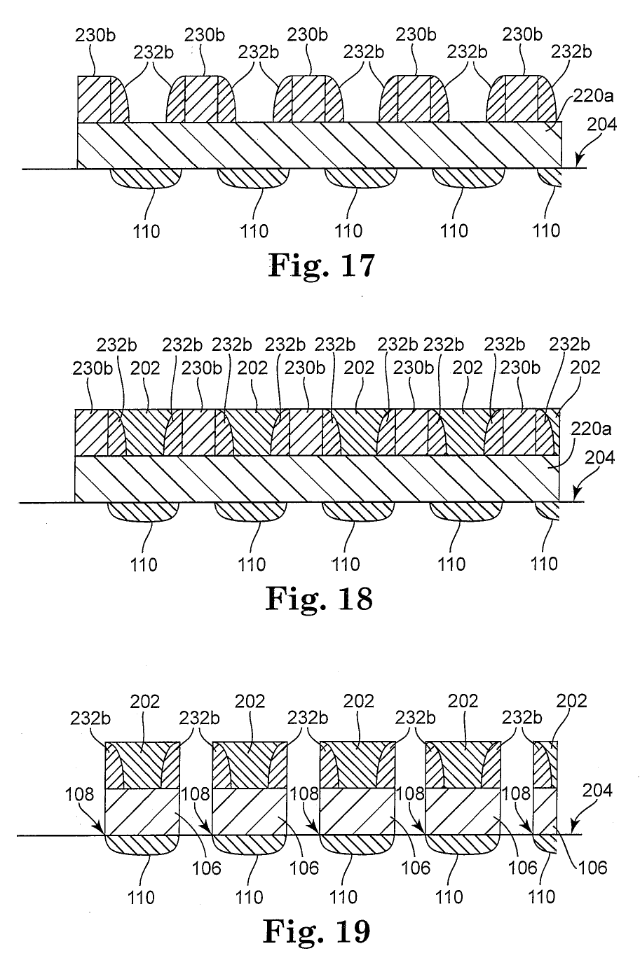

FIG. 17 illustrates a cross-sectional view of one embodiment of word lines 110, phase change material layer 220a, dielectric or sacrificial material layer 230b, and spacers 232b after etching spacer material layer 232a. Spacer material layer 232a is spacer etched to expose the top of dielectric or sacrificial material layer 230b and portions of phase change material layer 220a.

FIG. 18 illustrates a cross-sectional view of one embodiment of word lines 110, phase change material layer 220a, dielectric or sacrificial material layer 230b, spacers 232b, and heater contacts 202. An electrode material, such as TiN, TaN, W, Al, Ti, Ta, TiSiN, TaSiN, TiAlN, TaAlN, Cu, or other suitable electrode material is deposited over exposed portions of phase change material layer 220a, spacers 232b, and dielectric or sacrificial material layer 230b. The electrode material layer is planarized to expose the top of dielectric or sacrificial material layer 230b and to provide heater contacts 202. The electrode material layer is planarized using CMP or another suitable planarization technique.

FIG. 19 illustrates a cross-sectional view of one embodiment of word lines 110, diode junctions 108, phase change elements 106, heater contacts 202, and spacers 232b after removing dielectric or sacrificial material layer 230b and etching phase change material layer 220a. Dielectric or sacrificial material layer 230b is selectively removed using a selective etch to expose portions of phase change material layer 220a. The exposed portions of phase change material layer 220a are etched to expose portions of substrate 204 and to provide phase change elements 106. A diode junction 108 is formed at the interface between each word line 110 and phase change element 106. A storage location for storing one or more bits of data is formed in each phase change element 106 at the interface between each phase change element 106 and heater contact 202.

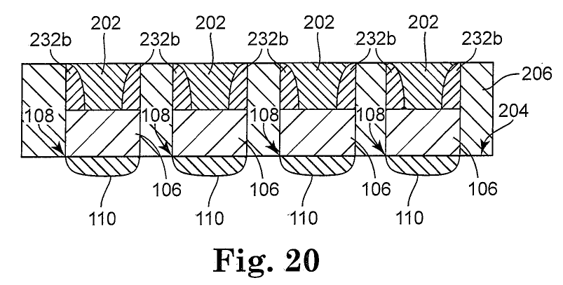

FIG. 20 illustrates a cross-sectional view of one embodiment of word lines 110, diode junctions 108, phase change elements 106, heater contacts 202, spacers 232b, and a dielectric material 206. Dielectric material, such as SiO₂, SiOₓ, SiN, FSG, BPSG, BSG, or other suitable dielectric material is deposited over exposed portions of substrate 204, phase change elements 106, spacers 232b, and heater contacts 202. The dielectric material layer is planarized to expose heater contacts 202. The dielectric material layer is planarized using CMP or another suitable planarization technique. Bit lines 112 are then formed above heater contacts 202 to provide an array of phase change memory cells similar to array of phase change memory cells 200a previously described and illustrated with reference to FIG. 2.

Embodiments of the present invention provide a diode phase change memory cell. The phase change material is used as both a storage location for data and one side of the diode junction of a diode for selecting the phase change memory cell for read or write access. In this way, a 4 F² memory cell is fabricated without an expensive and complex epitaxy process.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit having a memory comprising:
a semiconductor line; and
a phase change element contacting the semiconductor line, the phase change element providing a storage location,
wherein a diode junction is formed at the interface between the semiconductor line and the phase change element.

2. The integrated circuit of claim 1, further comprising:
a heater contact contacting the phase change element.

3. The integrated circuit of claim 2, further comprising:
a conductive line contacting the heater contact.

4. The integrated circuit of claim 1, wherein the semiconductor line comprises an n-type semiconductor material.

5. The integrated circuit of claim 1, wherein the semiconductor line is formed in a substrate.

6. The integrated circuit of claim 1, wherein the diode junction comprises a pn junction.

7. The integrated circuit of claim 1, wherein the diode junction comprises a Schottky junction.

8. A memory comprising:
word lines;
phase change elements coupled to the word lines, each phase change element providing a storage location for storing one or more data bits;
heater contacts, each heater contact coupled to a phase change element; and
bit lines coupled to the heater contacts,
wherein a diode junction is formed at the interface between each word line and phase change element.

9. The memory of claim 8, wherein the diode junction comprises a pn junction.

10. The memory of claim 8, wherein the diode junction comprises a Schottky junction.

11. The memory of claim 8, wherein the word lines comprise an n-type semiconductor material.

12. The memory of claim 8, wherein the word lines are formed in a substrate.

13. The memory of claim 8, wherein the word lines are isolated from each other by shallow trench isolation.

14. The memory of claim 8, wherein the word lines comprise n-type semiconductor material in a p-type well.

15. The memory of claim 8, wherein each heater contact has a sublithographic cross-section.

16. The memory of claim 8, wherein the phase change elements comprise at least one of Ge, Sb, Te, Ga, As, In, Se, and S.

17. A system comprising:
an array of memory cells, each memory cell comprising:
a semiconductor line; and
a phase change element contacting the semiconductor line, the phase change element providing a storage location;
wherein the semiconductor line and the phase change element form a diode;
means for writing data to the array of memory cells; and
means for reading data from the array of memory cells.

18. The system of claim 17, further comprising:
a controller for controlling the means for writing data and the means for reading data.

19. The system of claim 17, wherein each memory cell comprises a heater contact contacting the phase change element.

20. The system of claim 17, wherein the semiconductor line comprises a word line.

21. The system of claim 17, wherein each memory cell further comprises:
a bit line coupled to the phase change element.

22. A method for fabricating an integrated circuit including a memory, the method comprising:
forming word lines in a semiconductor substrate;
depositing a phase change material layer over the substrate;
depositing an electrode material layer over the phase change material layer;
etching the electrode material layer to provide heater contacts; and
etching the phase change material layer to provide phase change elements and diode junctions at an interface between each word line and phase change element.

23. The method of claim 22, wherein forming the word lines comprises forming the word lines by an implanting an n-type dopant into a p-type well.

24. The method of claim 22, wherein forming the word lines comprises forming the word lines by implanting a dopant into a substrate using shallow trench isolation as a mask.

25. The method of claim 22, further comprising:
conformally depositing a spacer material layer over exposed portions of the heater contacts and phase change material layer; and
spacer etching the heater contacts to expose portions of the phase change material layer,
wherein etching the phase change material layer comprises etching the exposed portions of the phase change material layer.

26. The method of claim 22, further comprising:
fabricating bit lines coupled to the heater contacts.

27. A method for fabricating a memory, the method comprising:
forming word lines in a semiconductor substrate;
depositing a phase change material layer over the substrate;
depositing a sacrificial material layer over the phase change material layer;
etching the sacrificial material layer to provide first openings exposing the phase change material layer;
conformally depositing a spacer material layer over exposed portions of the etched sacrificial material layer and the phase change material layer;
spacer etching the spacer material layer to provide second openings exposing the phase change material layer;
depositing electrode material into the second openings to form heater contacts; and
removing the etched sacrificial material layer to expose portions of the phase change material layer; and
etching the exposed portions of the phase change material layer to provide phase change elements and diode junctions at an interface between each word line and phase change element.

28. The method of claim 27, wherein the sacrificial material layer comprises a dielectric material layer.

29. The method of claim 27, wherein forming the word lines comprises forming the word lines by implanting an n-type dopant into a p-type well.

30. The method of claim 27, wherein forming the word lines comprises forming the word lines by implanting a dopant into a substrate using shallow trench isolation as a mask.

31. The method of claim 27, further comprising:
fabricating bit lines coupled to the heater contacts.
